(19) United States
(12) Patent Application Publication
(10) Pub. No.: US 2007/0095508 A1
(43) Pub. Date: May 3, 2007

(54) Heat dissipation device having louvered heat-dissipating fins

(75) Inventors: Wan-Lin Xia, Shenzhen (CN); Tao Li, Shenzhen (CN); Yong Zhong, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Foxconn Technology Co., Ltd., Tu-Cheng City (TW)

(21) Appl. No.: 11/265,346

(22) Filed: Nov. 2, 2005

(51) Int. Cl. H05K 7/20

(52) U.S. Cl. 165/104.33; 165/80.3; 361/700

(57) ABSTRACT

A heat dissipation device includes a base and a fin set arranged on the base. The fin set includes a plurality of spaced fins, a first end and a second end opposite to the first end. Pluralities of passages are defined between the fins and extending from the first end to the second end of the fin set. Each of the fins has a plurality of louvers defined therein and a plurality of tabs each extending along a side of each of the louvers from each of the fins. The louvers of the fins communicate with the passages between the fins. The tabs of each of the fins extend toward corresponding louvers of the adjacent fin. The passages communicate with ambient air at the first end and the second end of the fin set.

### BACKGROUND

1. Field

This invention is related to a heat dissipation device, and particularly to a heat dissipation device having louvered heat-dissipating fins for use in removing heat from a heat generating electronic device.

2. Related Art

It is well known that, during operation of a computer, electronic devices such as central processor units (CPUs) frequently generate large amounts of heat. The heat must be quickly removed from the electronic device to prevent the electronic device from becoming unstable or being damaged. Typically, heat dissipation devices are desired to dissipate heat generated by the electronic devices.

Conventionally, a heat dissipation device comprises a heat sink which has a base and a plurality of fins on the base. The fins each being flat sheet are parallel to each other and spaced arranged on the base. Therefore, pluralities of passages are defined between the fins for airflow passing therethrough. Generally, the heat dissipation device further comprises a fan for providing forced airflow to the heat sink. However, due to aerodynamics properties of fluid, a boundary layer is always formed at the interface of the fin and the airflow, which prevents cooling airflow from getting to the fin to have heat exchange with the fin. Additionally, each of the fins is flat; therefore, each of the passages between the fins is straight. Consequently, beyond the boundary layer, the airflow suffers from low resistance at a direction of flowing thereof. Thus, the cooling airflow speedily flows out of the passages without sufficient heat exchange with the fins. As a result, the fins of the heat sink is not fully utilized, the heat dissipation efficiency of the heat dissipation is not perfect. Thus, a new heat dissipation device is needed to meet the heat dissipation demand of the electronic device.

### SUMMARY

Accordingly, what is needed is to provide a heat dissipation device which has a capacity of having sufficient heat exchange with cooling airflow passing through the heat dissipation device.

A heat dissipation device in accordance with an embodiment of the present invention comprises a base having a first face and a second face opposite to the first face for contacting a heat generated electronic device, and a fin set arranged on the first face of the base. The fin set comprises a plurality of spaced fins, a first end and a second end opposite to the first end. Pluralities of passages are defined between the fins and extend from the first end to the second end of the fin set. Each of the fins has a plurality of louvers defined therein and a plurality of tabs each extending along a side of each of the louvers from each of the fins. The louvers of the fins communicate with the passages between the fins. The tabs of each of the fins extend toward corresponding louvers of an adjacent fin. The passages communicate with ambient air at the first end and the second end of the fin set. A fan is mounted to the first end of the fin set. When the fan operates, an airflow generated by the fan flows through the passages. The airflow in one passage can flow to an adjacent passage through corresponding louvers in the fin between the two passages.

Other advantages and novel features of the present invention will be drawn from the following detailed description of preferred embodiments of the present invention with the attached drawings, in which:

### BRIEF DESCRIPTION OF DRAWINGS

FIG. 1 is an exploded isometric view of a heat dissipation device in accordance with a preferred embodiment of the present invention;

FIG. 2 shows a fin set of FIG. 1;

FIG. 3 is a cross-sectional view taken along line III-III of FIG. 2;

FIG. 4 is an assembled view of FIG. 1 with a fan mounted thereon; and

FIG. 5 is an assembled view of a heat dissipation device in accordance with an alternative embodiment of the present invention.

### DETAILED DESCRIPTION

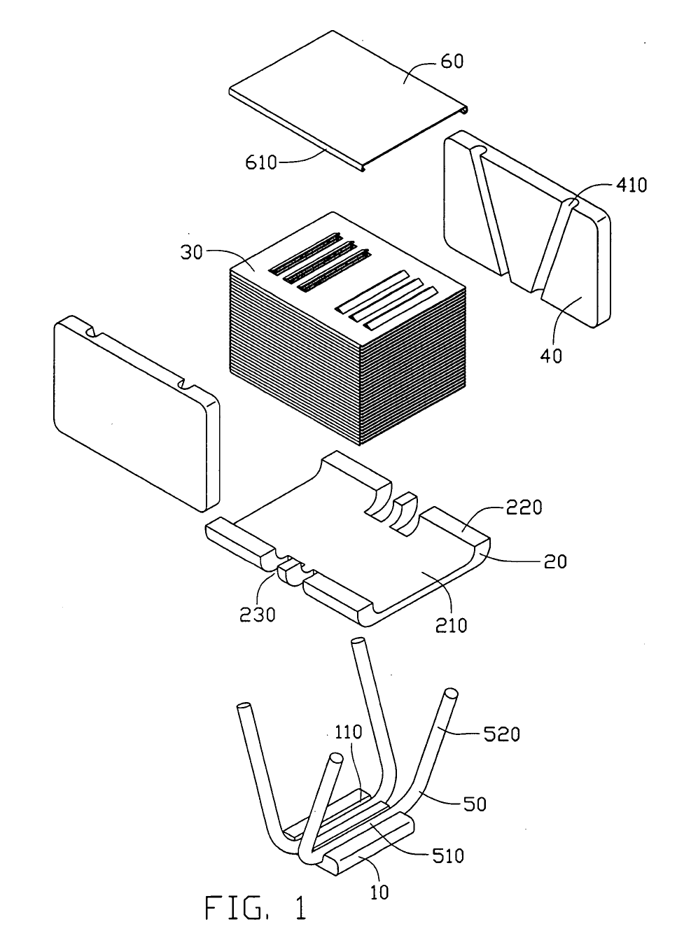

Referring to FIGS. 1-3, a heat dissipation device comprises a base 10, a bottom wall 20 on the base 10, a fin set 30 on the bottom wall 20, two sidewalls 40 located at two sides of the fin set 30, two heat pipes 50 connecting the base 10 and the two sidewalls 40 and a ceiling 60 on the fin set 30.

The base 10 is a substantially rectangular plate having a high heat conductivity. The base 10 has a top face defining two parallel grooves 110 therein and a bottom face opposite to the top face. The grooves 110 are for receiving the heat pipes 50, and the bottom face is for contacting with a heat generating electronic device, such as a CPU (central processing unit) (not shown).

The bottom wall 20 is substantially a rectangular plate arranged on the base 10. The bottom wall 20 comprises a flat portion 210 thermally contacting with the base 10 and two extension portions 220 integrally extending upwardly from two opposite sides of the flat portion 210. Each of the two extension portions 220 defines two cutouts 230 communicating with the grooves 110 of the base 10, respectively.

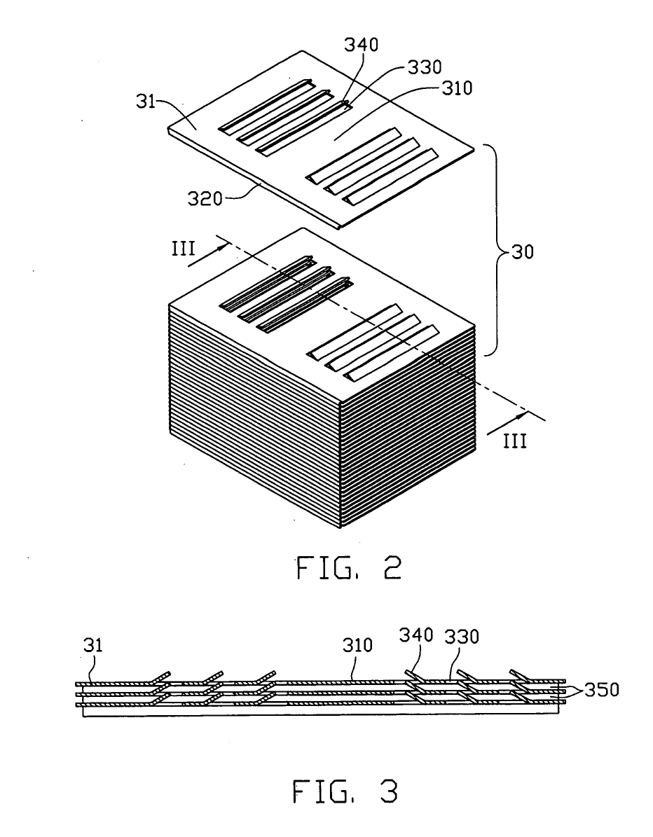

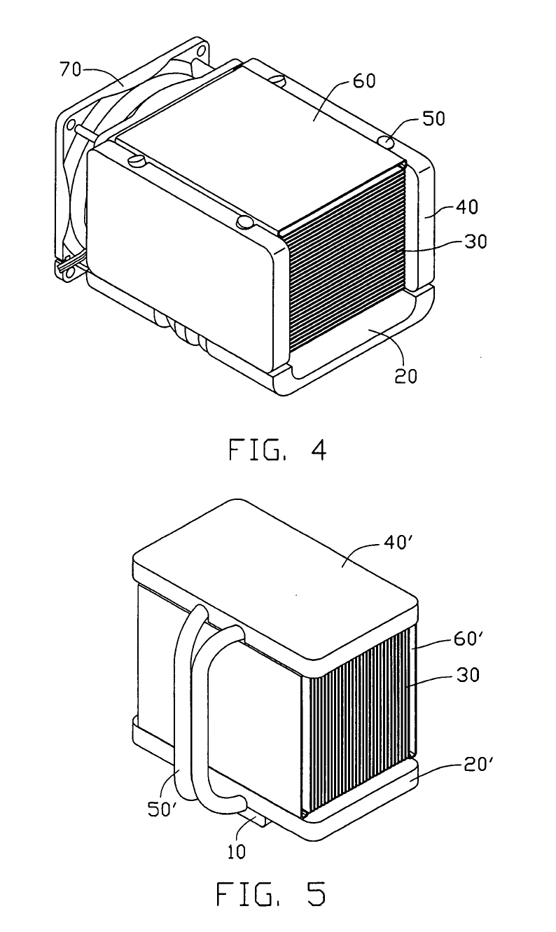

The fin set 30 comprises a plurality of fins 31 vertically stacked one by one. The fin set 30 horizontally rests on the two extension portions 220 above the flat portion 210 of the bottom wall 20. Each fin 31 is substantial rectangular, and has a body 310 and two flanges 320 perpendicularly and downwardly extending from two opposite edges of the body 310. The flanges 320 of each fin 31 abut against the body 310 of an adjacent fin 31 therebelow. The flanges 320 of each side of the fins 31 cooperatively form a contacting face for contacting a corresponding sidewall 40. Pluralities of passages 350 are defined between the fins 31. The body 310 can be generally divided into right and left portions along a middle thereof, as viewed from FIG. 2. Each portion defines a plurality of parallel elongated louvers 330 therein, extending along a direction perpendicular to the flanges 320 of the fins 31. A plurality of tabs 340 is formed by the body 310 of each fin 31 wherein each tab 340 is located corresponding to a respective louver 330. The tab 340 extends slantwise upwardly along a lengthwise side of a corresponding louver 330. The tabs 340 at the two portions incline toward each other. The louvers 330 and the tabs 340 of the two portions of the body 310 are symmetrical to each other. Each louver 330 of each fin 31 communicates adjacent two passages 350 above and below the fin 31. Each tab 340 of each fin 31 extends toward a corresponding louver 330 of an adjacent fin 30 thereabove.

The two sidewalls 40 are respectively disposed on the extension portions 220 of the bottom wall 20 and located at the two opposite sides of the fin set 30. Each of the sidewalls 40 is substantial rectangular and has an inner face defining two grooves 410 for receiving the heat pipes 50 therein. The two grooves 410 cooperatively form a substantially V-shaped contour. The inner faces of the sidewalls 40 respectively thermally contact the contacting faces of the fin set 30 constituted by the flanges 320. Therefore, the fin set 30 is sandwiched between the two sidewalls 40. The two sides of the fin set 30 are sealed by the two sidewalls 40.

Each of the two heat pipes is substantially U-shaped, and comprises working fluid therein. The working fluid has a phase change when a temperature thereof gets to a certain degree. Each heat pipe 50 comprises a first section 510 and two second sections 520 respectively perpendicularly extending from two ends of the first section 510. A rounder corner is formed at each joint of the sections 510,520 of the heat pipe 50. The first sections 510 of the heat pipe 50 are soldered into the grooves 110 of the base 10, respectively. The second sections 530 of the heat pipes 50 project upwardly beyond the base 10 and the bottom wall 20 from the cutouts 230 of the bottom wall 20, and are soldered into the grooves 410 of the sidewalls 40, respectively.

The ceiling 60 hoods on the fin set 30. The ceiling 60 has two flanges 610 depending from two opposite sides thereof. The two flanges 610 abut against two sides of a top of a top fin 31 of the fin set 30.

Therefore, the fin set 30 is surrounded by the bottom wall 20, the two sidewalls 40 and the ceiling 60. As a result, the passages 350 between the fins 31 communicate with ambient air only at two ends of the fin set 30. Furthermore, a fan 70 is located at one of the two ends of the fin set 30 to provide a forced airflow through the fin set 30.

In use, the heat dissipation device has the bottom face of the base 10 contacting the electronic device to absorb heat generated by the electronic device. Sequentially, the heat in the base 10 is absorbed by the first sections 510 of the heat pipes 50 and by the bottom wall 20. The first sections 510 are constructed as evaporators for the heat pipes 50. The heat in the first sections 510 of the heat pipes 50 reaches the sidewalls 40 via the second sections 520 of the heat pipes 50. The second sections 520 are constructed as condensers for the heat pipes 50. Also, part of the heat in the bottom wall 20 is conducted to the sidewalls 40 through a direction connection between the bottom wall 20 and the sidewalls 40. Then, the heat in the sidewalls 40 is transferred to the fin set 30 to be dissipated to the ambient air.

According to the first embodiment of the present invention, the louvers 330 of the fins 31 communicate the passages 350 between the fins 31, and the tabs 340 of the fins 31 extend toward the louvers 330; thus, when the fan 70 provides the forced airflow through the fin set 30, the tabs 340 guide the airflow to flow from one of the passages 350 to the adjacent upper one of the passages 350 via the louvers 330 between the two passages 350. As a result, the cooling airflow is facilitated to sufficiently contact with the fins 31 and have a full heat exchange with the fins 31. Therefore, in comparison with the conventional heat dissipation device, heat dissipation capacity of the heat dissipation device of the present invention is improved.

Additionally, the fins 31 are surrounded by the bottom wall 20, the sidewalls 40 and the ceiling 60; thus, the airflow between the fins 31 can only flow out of the heat dissipation device via the end opposite to the fan 70; by this, the airflow out of the heat dissipation device can cool other electronic devices located near the end of the heat dissipation device opposite the fan 70; therefore, the airflow of the fan 70 is fully utilized.

Furthermore, the heat dissipation device has two heat pipes 50 connecting the base 10 and the two sidewalls 40 thereof, and the fins 31 thermally contact the two sidewalls 40; therefore, the heat absorbed from the electronic device by the base 10 is rapidly transferred to the sidewalls 40 and then to the fins 31 to be dissipated.

Referring to FIG. 5, a heat dissipation device of an alternative embodiment of the present invention is shown. The heat dissipation device in accordance with this alternative embodiment comprises a bottom wall 20′, two side plates 60′ and a top wall 40′ cooperatively surrounding the fin set 30 therein. The bottom wall 20′ has a bottom face thermally contacting the base 10, and a top face on which the fin set 30 is arranged. The fin set 30 has a plurality of horizontally oriented fins wherein each fin thermally contacts with the top face of the bottom wall 20′. The fin set 30 has a structure the same as that of the previous embodiment; however, the fin set 30 of this alternative embodiment is vertically mounted on the bottom wall 20, rather than horizontally mounted like the previous embodiment. The two side plates 60′ each have two flanges at top and bottom sides thereof respectively. The two flanges are located on the two opposite sides of the fin set 30. The top wall 40′ is located on the fin set 30 opposite to the bottom wall 20′ and thermally contacts the fin set 30. Two heat pipes 50′ thermally connect the base 10, the bottom wall 20′, the fin set 30 and the top wall 40′. Top and bottom of the fin set 30 are sealed by the top and bottom wall 40′, 20′. Each heat pipe 50′ is generally U-shaped with a middle portion and two arms extending from two ends of the middle portion. One of the arms is thermally engaged between the base 10 and the bottom wall 20′ and the other of the arms is thermally engaged between the top of the fin set 30 and the top wall 40′.

It is to be understood, however, that even though numerous characteristics and advantages of the present invention have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A heat dissipation device comprising:
a base; and
a fin set comprising a plurality of spaced fins arranged on the base, a first end and a second end opposite to the first end, a plurality of passages being defined between the fins and extending from the first end to the second end of the fin set, each of the fins comprising a body having a plurality of louvers defined therein and a plurality of tabs each extending along a side of each of the louvers from each of the fins, the louvers communicating with the passages between the fins, the passages communicating with ambient air only at the first end and the second end the fin set.

2. The heat dissipation device of claim 1, wherein each of the fins comprises two flanges perpendicularly extending from two opposite edges of the body thereof, and wherein the two flanges of one of the fins abut against the body of an adjacent one of the fins.

3. The heat dissipation device of claim 2 further comprising two sidewalls located at two opposite sides of the fin set and seal the two sides of the fin set.

4. The heat dissipation device of claim 3, wherein the flanges of the fins of the fin set thermally contact the two sidewalls.

5. The heat dissipation device of claim 4 further comprising a heat pipe thermally connecting the base and the two sidewalls.

6. The heat dissipation device of claim 3 further comprising a ceiling on a top of the fin set.

7. The heat dissipation device of claim 6 further comprising a heat pipe, connecting the base and the ceiling.

8. The heat dissipation device of claim 6 further comprising a bottom wall located between the fin set and the base, wherein the fin set is mounted on the bottom wall.

9. The heat dissipation device of claim 1, wherein the tabs of each of the fins of the fin set are at a same side of the body of the fin, and extend toward corresponding louvers of the adjacent fin.

10. The heat dissipation device of claim 9, wherein the louvers of the each of the fins of the fin set are parallel and defined at two symmetrical portions of each of the fins.

11. The heat dissipation device of claim 10, wherein the tabs of two portions of each of the fins are symmetrical.

12. A heat dissipation device comprising:
a base; and
a fin set comprising a plurality of spaced fins arranged on the base, and a plurality of passages defined between the fins, each of the fins having a plurality of louvers defined therein and a plurality of tabs each extending along a side of each of the louver from each of the fins, the louvers communicating the passages between the fins, the tabs of each of the fins extending toward corresponding louvers of an adjacent fin.

13. The heat dissipation device of claim 12 further comprising two sidewalls sealing two opposite sides of the fin set.

14. The heat dissipation device of claim 13 further comprising a ceiling on a top of the fin set.

15. The heat dissipation device of claim 14 further comprising a heat pipe thermally connecting the base and the two sidewalls.

16. The heat dissipation device of claim 12, wherein the fin set has two ends thereof exposed to ambient air, and wherein a fan is located at one of the two ends to provide forced airflow through the fin set.

17. A heat dissipation device comprising:
a fin set having a plurality of fins each defining at least a louver therein;
an outer wall surrounding top, bottom and sides of the fin set to leave two opposite ends of the fin set exposed to atmosphere air, the outer wall having a bottom portion, a side portion and a top portion;
a heat pipe thermally connecting the bottom portion and one of the side portion and the top portion of the outer wall.

18. The heat dissipation device of claim 17 wherein the fins of the fin set are horizontally stacked on the bottom portion of the outer wall.

19. The heat dissipation device of claim 18 further comprising a fan mounted on one of the ends of the fin set, and wherein each of the fins forms at least an upwardly extending tab located neighboring the at least a louver.

20. The heat dissipation device of claim 17, wherein the fins of the fin set are oriented vertically on the bottom portion of the outer wall.
